(19) United States
(12) Patent Application Publication
(10) Pub. No.: US 2025/0118627 A1
(43) Pub. Date: Apr. 10, 2025

(54) HYBRID HEAT SINK

(71) Applicant: SIEMENS AKTIENGESELLSCHAFT, München (DE)

(72) Inventors: Hans Knauer, Leutenbach (DE); VOLKER MÜLLER, Nürnberg (DE); STEPHAN NEUGEBAUER, Erlangen (DE); FLORIAN SCHWARZ, Gerhardshofen (DE)

(73) Assignee: SIEMENS AKTIENGESELLSCHAFT, München (DE)

(21) Appl. No.: 18/728,617

(22) PCT Filed: Nov. 2, 2022
(86) PCT No.: PCT/EP2022/080491

§ 371 Date: Jul. 12, 2024

(30) Foreign Application Priority Data
Jan. 14, 2022 (EP) 22151500.0

(51) Int. Cl. H01L 23/427

(52) U.S. Cl. CPC H01L 23/427

(57) ABSTRACT

A hybrid heat sink includes a pulsating heat pipe and a liquid cooling unit which Includes a cover, with the pulsating heat pipe and the liquid cooling unit being arranged in layers on top of one another. The pulsating heat pipe is located between a heat source and the liquid cooling unit and is integrated in the cover of the liquid cooling unit.

The invention relates to a heat sink, a power module equipped with a heat sink of this type and a power converter equipped with a heat sink of this type, furthermore a method for producing a heat sink of this type.

With the advances in miniaturization in the field of microelectronics, the power density of electronic modules and thus also the heat flux density of heat generated by the electronic modules is increasing. Today, powerful electrical structural elements such as power semiconductors already generate thermal losses with heat flux densities of more than 100 W/cm², and rising. In order to avoid failures of electronics due to thermal overloads, increasingly more effective concepts for heat dissipation of the electrical structural elements are therefore needed.

An ideal heat sink has a homogeneous temperature distribution over the entire surface. This creates a maximum temperature gradient perpendicular to the surface for the respective maximum temperature at each point on the surface, which maximizes the heat flux. In order to effectively dissipate the lost heat by power semiconductor modules, water heat sinks are installed below the power modules.

In a power module, for example of a power converter, high temperature gradients form with hot spots under the semiconductor chips due to the discrete energy input and a limited heat distribution of the power module and the heat sink, wherein above all semiconductors reach higher temperatures in the middle of the module.

Nowadays, these requirements are taken into account by adapting the heat sink, e.g. by using larger heat sinks and larger fluid flow densities, or by using thicker base plates of the module or heat sink, or by using in most cases expensive materials with better specific thermal conductivity.

Furthermore, heat pipe heat sinks have already been established on the market for years for effective cooling of power modules. In this process, a liquid evaporates due to the heat input of a heat source in a closed pipe of the heat pipe heat sink. Due to the vacuum in the closed pipe, the liquid condenses at another point in the pipe, from which the heat can then be released into the ambient air, for example. The capillary effect is used to return the liquid in the pipe. For this purpose, the inside of the pipe is provided with a capillary structure.

US 2018/0158756 A1 discloses an integrated circuit apparatus with at least one semiconductor apparatus arranged on a substrate, wherein the substrate has a pulsating heat pipe embodied therein.

The disadvantage here is also the insufficient cooling efficiency, especially in power electronics devices.

Based on this, the object underlying the invention is to provide a heat sink that ensures improved heat dissipation from a power module or a power converter, and furthermore, this heat sink should be easy to manufacture.

The set object is achieved by a hybrid heat sink with at least one pulsating heat pipe and at least one liquid cooling unit, which are arranged in layers one on top of the other, wherein the pulsating heat pipe is located between a heat source and the liquid cooling unit.

The set object is also achieved by a power semiconductor unit with
an inventive hybrid heat sink,
at least one power semiconductor module, wherein the power semiconductor module is thermally conductively connected to the hybrid heat sink in such a way that the heat generated by power loss of the power semiconductor module is distributed over a large area by means of the pulsating heat pipe and can be dissipated via a liquid circuit, in particular a water circuit.

The set object is also achieved by a power converter with an inventive hybrid heat sink or an inventive power semiconductor unit.

The set object is achieved by a method of manufacturing a hybrid heat sink according to the invention with at least one pulsating heat pipe and a liquid cooling unit, which are arranged in layers one on top of the other, wherein the pulsating heat pipe is located between a heat source and the liquid cooling unit, by the following steps:
design of channels of the liquid cooling unit with inlets and outlets in a thermally conductive material block,
design of closed channels for a pulsating heat pipe in a cover,
filling of liquid into the channels of the cover to establish the functionality of the pulsating heat pipe,
assembling the material block and the cover.

The steps of the manufacturing process are not necessarily to be used in this order.

A pulsating heat pipe (PHP), which is also referred to as oscillating heat pipe (OHP), is an apparatus for heat transfer with a closed or open channel structure, in which a heat transport medium is arranged, which forms steam segments and liquid segments in an alternating manner along the channel structure due to the dominating surface tension of the heat transport medium. These steam and liquid segments are excited to pulsation or oscillation by a temperature gradient. At a heat source, the steam segments expand due to the higher temperature; liquid heat transport medium also boils there and in doing so absorbs latent heat. At a heat sink, the steam segments contract due to condensation of gaseous heat transport medium and in doing so emit latent heat. The local temperature and pressure differences drive the constant pulsation or oscillation of the steam and liquid segments.

In the operation of this Pulsating Heat Pipe (PHP), the capillary structure of a classic heat pipe is no longer required. In the case of the pulsating heat pipe, heat transfer also takes place via a fluid, wherein parts or sections of the fluid are present in gaseous form in the pipe or a channel. There are therefore alternating sections of different aggregate states along the pipe or channel, i.e. sections with liquid and sections with gas. Due to heat input, the sections in the pipe or channel begin to move back and forth.

For the pulsating heat pipes, the required channel structures can now be provided in a simple way as follows.

On the one hand, via a separate pipe system, which is preferably already filled with the liquid or a fluid in advance and is embedded in appropriate materials, preferably thermally conductive materials.

On the other hand, the channel structures can also be established by incorporating corresponding recesses into a preferably thermally conductive material. These recesses are covered and filled with the necessary liquid.

The inside of the pipe or a channel can therefore also be smooth, which simplifies production.

Water, acetone or methanol or other fluids or liquids that can be used in a pipe or channel with a diameter<3 mm are particularly suitable as fluids or liquids.

According to the invention, the pulsating heat pipes result in heat spreading, preferably essentially flat heat spreading, which, together with a liquid cooling unit, creates a highly efficient hybrid heat sink.

The heat source, for example a power semiconductor or a power converter, has one or more hot spots, i.e. an uneven heat distribution. Due to the heat emitted unevenly to the layer with the pulsating heat pipes, heat spreading and homogenization of the heat now occurs in this layer due to the pulsating heat pipe. As a result, the liquid cooling unit can absorb this heat comparatively well and dissipate it efficiently.

This existing heat spread makes the exact positioning of the liquid cooling channels within the hybrid heat sink less relevant. As a result, these liquid cooling channels no longer necessarily have to run directly under the hot spots, but can be moved to the areas within the hybrid heat sink that are inter alia more suitable for mountability, or even eliminated.

The pulsating heat pipe (PHP) can now be used to provide a hybrid heat sink at low cost, which has a comparatively high cooling effect.

Recesses—i.e. the later channels of the liquid cooling unit—are preferably incorporated machined, especially milled, into a material block. By means of a vacuum brazing or welding process, a cover is placed on the base plate, which closes the milled recesses of the liquid cooling unit. Only inlets and outlets are provided for the liquid cooling unit. The recesses run in the interface or surface of the material block so that they can be easily covered with a cover.

In one design, the flow directions of the liquid cooling unit and the pulsating heat pipe run transversely, especially perpendicular to each other. This improves the heat transfer and thus the heat dissipation.

The integration of a pulsating heat pipe into the first layer of the hybrid heat sink increases the thermal conductivity many times over, thus significantly improving thermal efficiency. This means that more expensive materials, such as copper, can be dispensed with, especially with comparatively better cooling performance. In general, however, all structurally sufficiently stable (and formable) materials are conceivable, e.g. also electrically insulating or extremely corrosion-resistant or wear-resistant materials.

Preferably, the cover and/or material block of the liquid cooling unit is made of aluminum or of a thermally conductive plastic. These are available on the market, can be produced inexpensively and have a sufficiently good thermal conductivity.

The structures of one or more pulsating heat pipes within the cover run in a kind of snake shape, meander shape or U-shape, wherein the resulting distances between the bends can be adjusted in order thus to obtain a higher density of the pulsating heat pipes also in areas, potential hot spots, of the power semiconductor or power converter.

It is not only the channel structures of the liquid cooling unit and/or the pulsating heat pipes that can be embossed, milled, drilled, 3D printed, sprayed and cast, in particular also with lost form, but also the attachment elements for the inlets and outlets in and out of the respective channel structures.

The heat source, for instance a semiconductor, is attached to the base plate at higher powers and thus associated power losses, also known as power semiconductors. This base plate is attached to a cover that contains or covers the pulsating heat pipes in a thermally conductive manner. The cover covers the recesses of the material block and thus forms the channels of the liquid cooling unit.

This layer-type structure of the hybrid heat sink ensures high cooling efficiency through heat spreading.

The base plate and the cover, as well as the cover with the material block, can be permanently connected to each other, for example, by means of soldering, welding, gluing, clamping, pressing or another process.

Comparatively high amounts of heat can be transported away from the heat source by such a hybrid heat sink without any significant time delay. In addition, the hybrid heat sink can be assembled easily, efficiently and cost-effectively from just a few parts.

The layer-like structure of the hybrid heat sink can not only take place in planar planes, but the individual layers can also be bent in a complementary way to adapt to curved heat sources, for example.

In this process, the individual layers are first shaped or bent and then—as described above—assembled to form a hybrid heat sink.

Further advantageous embodiments of the invention are specified in the dependent claims.

The invention and further advantageous embodiments thereof will now be explained in greater detail on the basis of schematic representations of exemplary embodiments, in which:

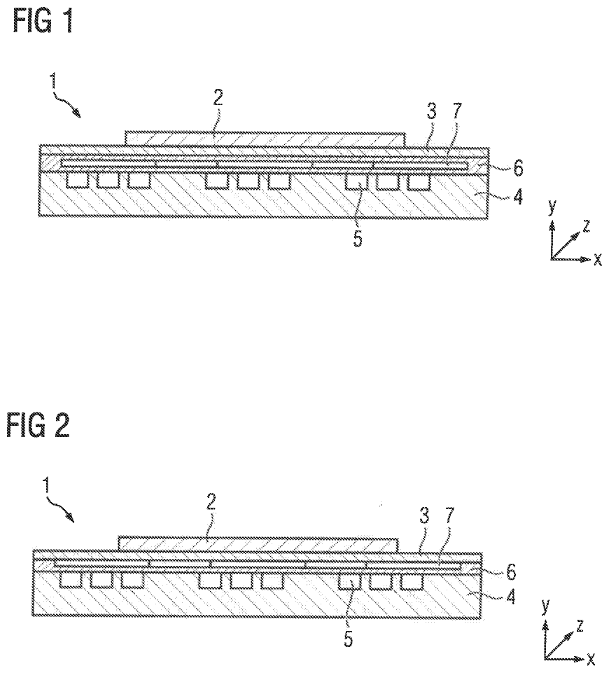

FIG. 1 shows a section through a hybrid heat sink,

FIG. 2 shows a section through a further hybrid heat sink,

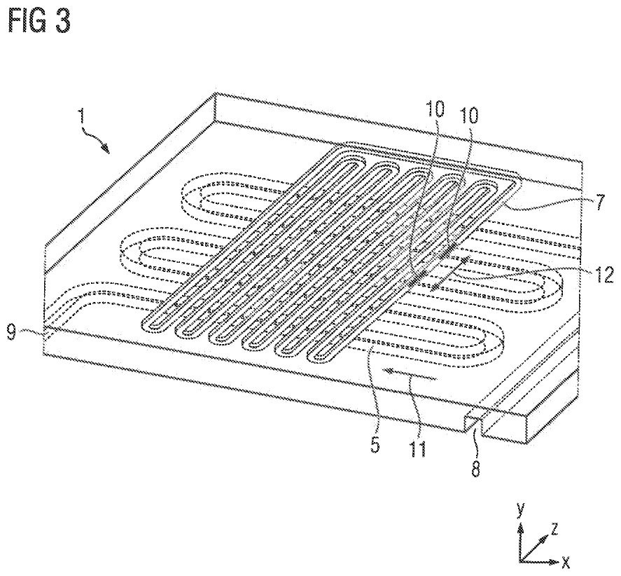

FIG. 3 shows a perspective representation of a hybrid heat sink,

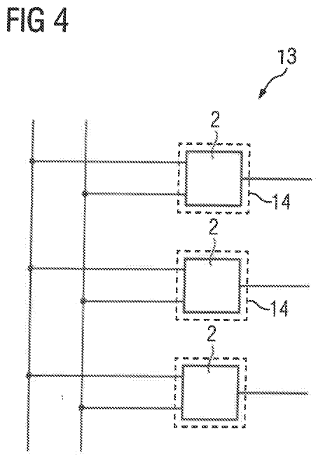

FIG. 4 shows a power converter with power modules.

It should be noted that the term “coaxial components”, for instance coaxial components, is understood here to mean components which have the same normal vectors, for which the planes defined by the coaxial components are parallel to each other. Furthermore, the expression should imply that the centers of coaxial components lie on the same axis of rotation or symmetry. The expression does not necessarily require that coaxial components have the same radius.

The term “complementary” means, in the context of two components that are “complementary” to each other, that their external shapes are designed in such a way that one component can preferably be arranged completely in the component that is complementary to it, so that the inner surface of one component and the outer surface of the other component ideally fit seamlessly or completely touch. Consequently, in the case of two complementary objects, the external shape of one object is determined by the external shape of the other object. The term “complementary” could be replaced by the term “inverse”.

For the sake of clarity, sometimes in cases where components are duplicated, not all of these components are provided with reference signs in the figures.

The versions described below can be combined as desired. Likewise, individual features of the respective designs can also be combined without leaving the essence of the invention.

FIG. 1 shows a hybrid heat sink 1 in a section, which is layered in an attached Cartesian coordinate system (xyz) in the y-direction. This layering is represented as follows: liquid cooling unit 4, cover 6 of the liquid cooling unit with PHP 7. Thereabove, a base plate 3 of a heat source, an electronics module or a power module 2 is thermally connected. The base plate 3 does not necessarily have to be designed over the entire surface.

In principle, a power semiconductor, e.g. a MOSFET or an IGBT, can be considered as the heat source of a power module 2.

The power module 2 is positioned on a thermally conductive base plate 3. A cover 6 of the liquid cooling unit with an integrated pulsating heat pipe 7 connects hereto. To design the liquid cooling unit, recesses which preferably open upwards (y-direction) are incorporated in a thermally conductive material block. These open recesses are closed by the cover 6, as a result of which channels 5 of the liquid cooling unit form. The recesses located on the surface of the material block or boundary layer can be worked out of the material block comparatively easily, e.g. by milling processes. The material block, as well as the other components involved in the thermal conduction process, are made of aluminum or its alloys or copper and its alloys or other thermally conductive materials.

According to this design, the cover is hollow and can therefore accommodate one or more closed pulsating heat pipes 7, which were inserted from the z-direction, in the cavity, for example. The cover is then sealed.

FIG. 2 shows a version of a heat sink 4 identical to FIG. 1, but which is closed towards the base plate 3 with a cover 6 which is open to the y-direction. This cover 6 also accommodates one or more closed pulsating heat pipes 7 in each case. These are inserted into the cover 6 from the y-direction and closed with a base plate 3 of the power module 2.

The pulsating heat pipe 7 is therefore closed directly with the base plate 3 of the power module 2. As a result, fewer components are required for the hybrid heat sink 1 and the thermal path from the heat source to the liquid cooling unit is shortened, which further increases cooling efficiency.

The pulsating heat pipe 7 is therefore either inserted as a closed pipe unit in complementary recesses of the cover 6 and/or is surrounded by thermal conductive paste in order to obtain a heat spread according to both FIG. 1 and FIG. 2.

However, channels or capillaries or channel structures can also be incorporated, etched, milled, etc., into the cover 6 and then sealed and filled with the appropriate liquid or fluids to form the pulsating heat pipe 7.

These channels or capillaries or channel structures of the pulsating heat pipe are preferably dimensioned in such a way that capillary effects are achieved within the channel or capillary or channel structure, but the flow resistance of the channel or capillary or channel structures remains limited. Depending on the medium filled, there are usually cross-sectional dimensions of the channels or capillaries or channel structures between 0.5 mm and 8 mm, preferably between 1.5 mm and 3 mm.

FIG. 3 shows a possible structure of a hybrid heat sink 1 according to the invention with an integrated pulsating heat pipe 7 in the heat sink 4 of a water cooling system. Channels or capillaries or channel structures are incorporated, e.g. milled, into the heat sink 4 of the water cooling system, essentially transverse to the water cooling channels 5. Now another cover or a base plate 3 is needed for the layer of the hybrid heat sink 1, which forms the pulsating heat pipe 7.

The liquid cooling unit as well as the pulsating heat pipe 7 meander in the x-z plane, wherein their main flow direction is represented by arrows 11, 12. The heat transport takes place in the y-direction, in which the layering of the hybrid heat sink 1 also takes place.

In a single process step, the entire layer-like composite (heat sink with water channel, cover with PHP and the cover of the PHP) is now closed during production.

Basically, the lost heat of the power module 2 on the underside of the base plate 3 is now distributed over a large area by the pulsating heat pipe 7 and can therefore be better absorbed and dissipated by the liquid cooling unit. This heat spread of the pulsating heat pipe 7 thus increases the heat transport from the power module 2 to the liquid cooling unit.

The pulsating liquid-gas mixture inside the channel of the pulsating heat pipe 7 is indicated by the double arrows 12. The flow direction of the liquid of the liquid cooling unit is marked with arrows 11.

For the closing and, if necessary, filling of the channels or capillaries or channel structures, end parts which are not represented in more detail are used. As part of the production of the hybrid heat sink 1, the pulsating heat pipe 7 is shaped into a desired shape, e.g. meander shape or U-shape, at the bending points.

The meander-shaped part of the pulsating heat pipe 7 has bends that have an angle of approx. 180°. Other bending shapes are also conceivable.

The layer-like structure of the hybrid heat sink 1 can not only take place in planar planes. The individual layers can also be bent in a complementary way to adapt to curved heat sources, for example.

In this process, the individual layers (i.e. heat sink 4 and cover with pulsating heat pipe 7) are first shaped or bent and then—as described above—assembled to form a hybrid heat sink 1.

FIG. 4 shows a power converter 13 with three power semiconductor units 14. The power semiconductor units 14 each have at least one power semiconductor module 2. The power semiconductor module 2 is cooled or deheated by means of a hybrid heat sink 1, which is not shown in more detail here. The hybrid heat sink 1 is designed according to one of the figures explained above.

What is claimed is:

1.-9. (canceled)

10. A hybrid heat sink, comprising:
a pulsating heat pipe; and
a liquid cooling unit including a cover,
wherein the pulsating heat pipe and the liquid cooling unit are arranged in layers on top of one another,
wherein the pulsating heat pipe is located between a heat source and the liquid cooling unit, and
wherein the pulsating heat pipe is integrated in the cover of the liquid cooling unit.

11. The hybrid heat sink of claim 10, wherein the pulsating heat pipe is integrated in a base plate of the heat source.

12. The hybrid heat sink of claim 10, wherein the liquid cooling unit is embodied as a water cooling system.

13. The hybrid heat sink of claim 10, wherein at least one of the layer of the pulsating heat pipe and the layer of the liquid cooling unit has flat, planar layers.

14. The hybrid heat sink of claim 10, wherein at least one of the layer of the pulsating heat pipe and the layer of the liquid cooling unit has curved layers.

15. A power semiconductor unit, comprising:
a hybrid heat sink comprising a pulsating heat pipe and a liquid cooling unit which includes a cover, wherein the pulsating heat pipe and the liquid cooling unit are arranged in layers on top of one another, with the pulsating heat pipe being integrated in the cover of the liquid cooling unit; and
a power semiconductor module thermally conductively connected to the hybrid heat sink in such a way that the pulsating heat pipe is located between the power semiconductor module and the liquid cooling unit so that heat generated by power loss of the power semiconductor module is distributed over a large area via the pulsating heat pipe and is dissipated via a liquid circuit.

16. The power semiconductor unit of claim 15, wherein the liquid circuit is a water circuit.

17. The power semiconductor unit of claim 15, wherein the pulsating heat pipe is integrated in a base plate of the power semiconductor module.

18. The power semiconductor unit of claim 15, wherein the liquid cooling unit is embodied as a water cooling system.

19. The power semiconductor unit of claim 15, wherein at least one of the layer of the pulsating heat pipe and the layer of the liquid cooling unit has flat, planar layers.

20. The power semiconductor unit of claim 15, wherein at least one of the layer of the pulsating heat pipe and the layer of the liquid cooling unit has curved layers.

21. A power converter, comprising:
a hybrid heat sink comprising a pulsating heat pipe and a liquid cooling unit including a cover, wherein the pulsating heat pipe and the liquid cooling unit are arranged in layers on top of one another, wherein the pulsating heat pipe is located between a heat source and the liquid cooling unit, and wherein the pulsating heat pipe is integrated in the cover of the liquid cooling unit; or
the power semiconductor unit as set forth in claim 15.

22. A method for producing a hybrid heat sink, comprising:
arranging a pulsating heat pipe and a liquid cooling unit in layers on top of one another;
locating the pulsating heat pipe between a heat source and the liquid cooling unit by
designing channels of the liquid cooling unit with inlets and outlets in a thermally conductive material block,
designing closed channels for the pulsating heat pipe in a cover of the liquid cooling unit,
filling liquid into the channels of the cover to establish functionality of the pulsating heat pipe, and
assembling the material block and the cover.
